(19) United States
(12) Patent Application Publication
(10) Pub. No.: US 2024/0094991 A1
(43) Pub. Date: Mar. 21, 2024

(54) PSEUDORANDOM BINARY SEQUENCES GENERATION

(71) Applicant: Micron Technology, Inc., Boise, ID (US)

(72) Inventors: Marco Sforzin, Cernusco Sul Naviglio (IT); Daniele Balluchi, Cernusco Sul Naviglio (IT)

(21) Appl. No.: 17/945,260

(22) Filed: Sep. 15, 2022

(51) Int. Cl. G06F 7/58; G11C 11/4076; H03K 3/84; H03K 19/21

(52) U.S. Cl. CPC G06F 7/582; G11C 11/4076; H03K 3/84; H03K 19/21

(57) ABSTRACT

Methods, systems, and devices related to generating, by a pseudorandom binary sequence (PRBS) generator of a memory module, a PRBS comprising a first plurality of bits corresponding to a plurality of cycles of a clock signal of the memory module subsequent to a current cycle of the clock signal. Generation of the PRBS can be based on an intermediate PRBS comprising a second plurality of bits corresponding to the current cycle of the clock signal. During each respective cycle of the clock signal, a respective subset of the PRBS can be communicated from the PRBS generator to a memory device of the memory module. Each respective subset of the PRBS comprises a quantity of bits based on a frequency of a data strobe signal of the memory device relative to a frequency of the clock signal.

### TECHNICAL FIELD

The present disclosure relates generally to semiconductor memory and methods, and more particularly, to apparatuses, systems, and methods of generating pseudorandom binary sequences.

### BACKGROUND

Memory devices are typically provided as internal, semiconductor, integrated circuits in computers or other electronic systems. There are many different types of memory including volatile and non-volatile memory. Volatile memory can require power to maintain its data (e.g., host data, error data, etc.) and includes Random Access Memory (RAM), Dynamic Random Access Memory (DRAM), Static Random Access Memory (SRAM), Synchronous Dynamic Random Access Memory (SDRAM), and Thyristor Random Access Memory (TRAM), among others. Non-volatile memory can provide persistent data by retaining stored data when not powered and can include NAND flash memory, NOR flash memory, Ferroelectric Random Access Memory (FeRAM), and resistance variable memory such as Phase Change Random Access Memory (PCRAM), Resistive Random Access Memory (RRAM), and Magnetoresistive Random Access Memory (MRAM), such as Spin Torque Transfer Random Access Memory (STTRAM), among others.

Memory devices may be coupled to a host (e.g., a host computing device) to store data, commands, and/or instructions for use by the host while the computer or electronic system is operating. For example, data, commands, and/or instructions can be transferred between the host and the memory device(s) during operation of a computing or other electronic system. A controller may be used to manage the transfer of data, commands, and/or instructions between the host and the memory devices.

### BRIEF DESCRIPTION OF THE DRAWINGS

FIG. 1 illustrates a functional block diagram in the form of a computing system including a controller for generating a pseudorandom binary sequence (PRBS) in accordance with a number of embodiments of the present disclosure.

FIG. 2 is a block diagram representing flip-flops of a PRBS generator in accordance with a number of embodiments of the present disclosure.

FIG. 3 illustrates a set of expressions illustrative of generating a PRBS in accordance with a number of embodiments of the present disclosure.

FIG. 4 illustrates sets of expressions and corresponding matrices illustrative of generating a PRBS in accordance with a number of embodiments of the present disclosure.

FIG. 5 is a block diagram of a PRBS generator in accordance with a number of embodiments of the present disclosure.

FIG. 6 is a block diagram of a PRBS generator in accordance with a number of embodiments of the present disclosure.

FIG. 7 is a flow diagram of a method for generating a PRBS in accordance with a number of embodiments of the present disclosure.

### DETAILED DESCRIPTION

Systems, apparatuses, and methods related to generating a pseudorandom binary sequence (PRBS) are described. Some previous approaches include a PRBS generator that generates pseudorandom binary value (also referred to herein as a bit) of a PRBS each cycle of a clock signal (also referred to herein as a clock cycle). In some previous approaches, a controller may include a PRBS generator. The controller may communicate a respective bit of the PRBS to a memory device as part of a read operation or a write operation, for instance. In some previous approaches, a frequency of a data strobe signal of a memory device may be the same as a frequency received by a controller. However, this is not always the case.

A data strobe of a memory device, for instance, can operate at a frequency greater than (e.g., 8 or 16 times faster than) the frequency of a clock signal. Such a mismatch between a clock signal and a data strobe signal can be problematic because a controller communicates a single bit of a PRBS each clock cycle when a memory device needs to receive multiple bits of the PRBS during a single clock cycle. For instance, performing operations associated with built-in self-test (BIST) of a memory device having a data strobe signal faster than a clock signal can require receipt of multiple bits of a PRBS during a single clock cycle.

Aspects of the present disclosure address the above and other deficiencies of previous approaches. Some embodiments of the present disclosure include generating a PRBS at a faster frequency than the frequency of a clock signal such that multiple bits of a PRBS (e.g., a vector of bits of a PRBS) can be provided to a controller during a single clock cycle. This enables operations associated with a data strobe signal of a memory device, such as operations associated with BIST, to be performed at a frequency of the data strobe signal even if the frequency of the data strobe signal is faster than the frequency of a clock signal. In some embodiments, during a single clock cycle, bits of a PRBS can be generated corresponding to multiple clock cycles (e.g., a current clock cycle and one or more clock cycles subsequent to the current clock cycle). In various embodiments, multiple bits of a PRBS can be generated and communicated to a memory device during a single clock cycle. As described herein, the quantity of bits (how many bits) of a PRBS that are output by a PRBS generator during a single clock cycle can be based on the frequency of a data strobe signal.

As used herein, the singular forms “a,” “an,” and “the” include singular and plural referents unless the content clearly dictates otherwise. Furthermore, the word “may” is used throughout this application in a permissive sense (i.e., having the potential to, being able to), not in a mandatory sense (i.e., must). The term “include,” and derivations thereof, mean “including, but not limited to.” As used herein, “coupled to” or “coupled with” generally refers to a connection between components, which can be an indirect communicative connection or direct communicative connection (e.g., without intervening components), whether wired or wireless, including connections such as electrical, optical, magnetic, and the like. The terms “data” and “data values” are used interchangeably herein and can have the same meaning, as appropriate to the context.

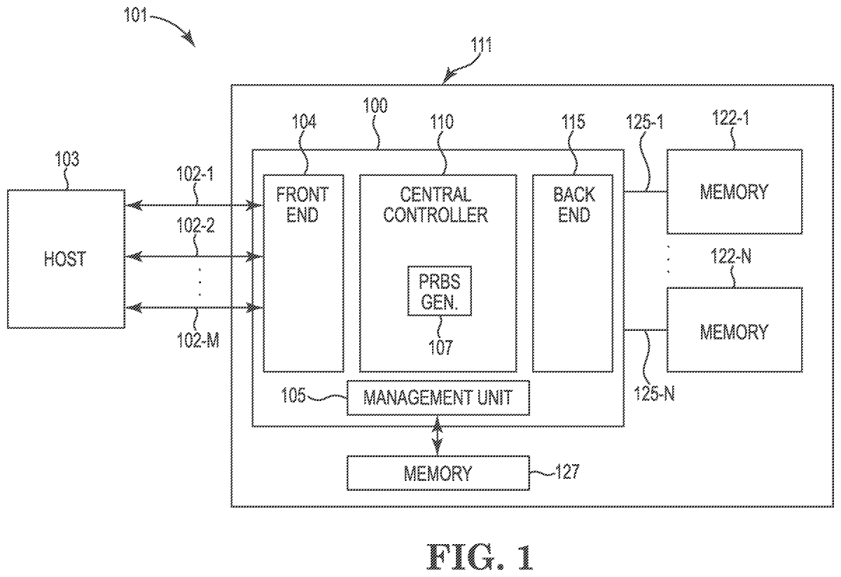

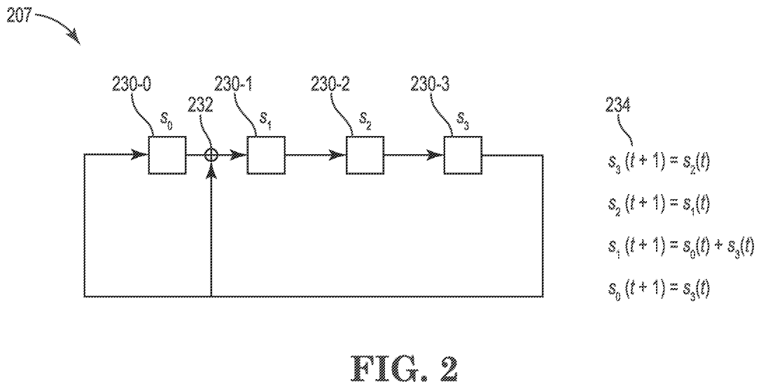

The figures herein follow a numbering convention in which the first digit or digits correspond to the drawing figure number and the remaining digits identify an element or component in the drawing. Similar elements or components between different figures may be identified by the use of similar digits. For example, element 107 can represent element 7 in FIG. 1, and a similar element can be labeled 207 in FIG. 2. Analogous elements within a figure may be referenced with a hyphen and extra numeral or letter. As will be appreciated, elements shown in the various embodiments herein can be added, exchanged, and/or eliminated so as to provide a number of additional embodiments of the present disclosure. In addition, as will be appreciated, the proportion and the relative scale of the elements provided in the figures are intended to illustrate certain embodiments of the present invention and should not be taken in a limiting sense.

FIG. 1 illustrates a functional block diagram in the form of a computing system 101 including a controller 100 (which may be referred to as a “memory controller”) for generating a PRBS in accordance with a number of embodiments of the present disclosure. The computing system 101 includes a memory module 111. The memory module 111 can include the controller 100 and one or more memories and/or memory devices coupled thereto.

The controller 100 can include a front end portion 104, a central controller portion 110, and a back end portion 115. The computing system 101 can further include a host 103, memory devices 122-1, . . . , 122-N (collectively referred to as memory devices 122), and a memory 127. The memory 127 can be a flash memory accessible via a serial peripheral interface (SPI). The memory 127 can include other circuitry, firmware, software, or the like, whether alone or in combination.

The front end portion 104 includes an interface to couple the controller 100 to the host 103 through input/output (I/O) lanes 102-1, 102-2, . . . , 102-M (collectively referred to as I/O lanes 102). The front end portion includes interface management circuitry to manage the I/O lanes 102. The front end portion can include any quantity of the I/O lanes 102 (e.g., eight, sixteen I/O lanes 102). In some embodiments, the I/O lanes 102 can be configured as a single port. In some embodiments, the interface between the controller 100 and the host 103 can be a Peripheral Component Interconnect express (PCIe) physical and electrical interface operated according to a Compute Express Link (CXL) protocol.

In some embodiments, the computing system 101 can be a CXL compliant memory system (e.g., the memory system can include a PCIe/CXL interface). CXL is a high-speed central processing unit (CPU)-to-device and CPU-to-memory interconnect designed to accelerate next-generation data center performance. CXL technology maintains memory coherency between the CPU memory space and memory on attached devices, which allows resource sharing for higher performance, reduced software stack complexity, and lower overall system cost.

CXL is designed to be an industry open standard interface for high-speed communications, as accelerators are increasingly used to complement CPUs in support of emerging applications such as artificial intelligence and machine learning. CXL technology is built on the peripheral component interconnect express (PCIe) infrastructure, leveraging PCIe physical and electrical interfaces to provide advanced protocol in areas such as I/O protocol, memory protocol (e.g., initially allowing a host to share memory with an accelerator), and coherency interface.

Although not illustrated by FIG. 1, the central controller portion 110 can include a cache memory (alternatively referred to as a cache). In some embodiments, in response to receiving a read request for data stored in the cache memory, the data can be provided to the host 103 as requested without further accessing the memory device 122. In some embodiments, in response to receiving a write request, data can be stored in the cache memory prior to writing the data to the memory device 122.

The central controller portion 110 can control, in response to receiving a memory access request from the host 103, for example, performance of one or more memory operations. Non-limiting examples of memory operations include a memory operation to read data from the cache memory and/or a memory device 122 and an operation to write data to the cache memory and/or a memory device 122. In some embodiments, the central controller portion 110 can control writing of multiple pages of data substantially simultaneously.

As used herein, the term “substantially” intends that the characteristic may not be absolute, but is close enough so as to achieve the advantages of the characteristic. For example, “substantially simultaneously” is not limited to operations that are performed absolutely simultaneously and can include timings that are intended to be simultaneous but due to manufacturing limitations may not be precisely simultaneously. For example, due to read/write delays that may be exhibited by various interfaces, media controllers that are utilized “substantially simultaneously” may not start or finish at exactly the same time. For example, the multiple memory controllers can be utilized such that they are writing data to the memory devices at the same time regardless if one of the media controllers commences or terminates prior to the other.

The back end portion 115 can include media control circuitry and a physical (PHY) layer that couples the controller 100 to the memory devices 122. As used herein, the term “PHY layer” generally refers to the physical layer in the Open Systems Interconnection (OSI) model of a computing system. The PHY layer can be the first (e.g., lowest) layer of the OSI model and used to transfer data over a physical data transmission medium. In some embodiments, the physical data transmission medium can include channels 125-1, . . . , 125-N (collectively referred to as the channels 125). The channels 125 can include a sixteen-pin data bus and a two pin data mask inversion (DMI) bus, for example, among other possible buses. The channels 125 can each include an input/output data (DQ) bus and a data strobe (DQS) bus. The back end portion 115 can communicate (e.g., transmit and/or receive) data to and/or from the memory devices 122 via the data pins.

One or more of the memory devices 122 can include dynamic random access memory (DRAM). DRAM can be operated according to a protocol, such as low-power double data rate (LPDDRx), (e.g., LPDDRx DRAM devices, LPDDRx memory, etc). The “x” in LPDDRx refers to any of a number of generations of the protocol (e.g., LPDDR5). In some embodiments, at least one of the memory devices 122 is operated as an LPDDRx DRAM device with low-power features enabled and at least one of the memory devices 122 is operated as an LPDDRx DRAM device with at least one low-power feature disabled. In some embodiments, the memory devices 122 are LPDDRx memory devices, but the memory devices 122 do not include circuitry configured to provide low-power functionality, such as a dynamic voltage frequency scaling core (DVFSC), a sub-threshold current reduce circuit (SCRC), or other low-power functionality providing circuitry. The LPDDRx memory devices 122 without such circuitry can advantageously reduce the cost, size, and/or complexity of the LPDDRx memory devices 122. By way of example, an LPDDRx memory device with reduced low-power functionality providing circuitry can be used for applications other than mobile applications (e.g., if the memory is not intended to be used in a mobile application, some or all low-power functionality can be sacrificed for a reduction in the cost of producing the memory).

In some embodiments, the memory controller 100 can include a management unit 105 to initialize, configure, and/or monitor characteristics of the memory controller 100. The management unit 105 can include an I/O bus to manage out-of-band data and/or commands, a management unit controller to execute instructions associated with initializing, configuring, and/or monitoring the characteristics of the memory controller, and a management unit memory to store data associated with initializing, configuring, and/or monitoring the characteristics of the memory controller 100. As used herein, the term “out-of-band data and/or commands” generally refers to data and/or commands transferred through a transmission medium that is different from the main transmission medium of a network. For example, out-of-band data and/or commands can be data and/or commands transferred to a network using a different transmission medium than the transmission medium used to transfer data within the network.

As illustrated by FIG. 1, the central controller portion 110 can include a PRBS generator 107. However, in some embodiments, the PRBS generator 107 can be a component of a different portion of the controller 100 or external to the controller 100. The PRBS generator 107 can include flip-flops. In some embodiments, the flip-flops can be a part of a linear-feedback shift register (LFSR). As used herein, an “LFSR” refers to a shift register that has an input that is a linear function of a previous state of the input. A PRBS may depend on a seed value. As used herein, “seed value” refers to an initial value (e.g., an initial binary value) on which a PRBS is based. A seed value may be programmed (by a manufacturer or an end user) and stored in one or more registers of a controller of a memory device, for example.

The flip-flops can generate a bit of an intermediate PRBS each cycle of a clock signal. As used herein, “intermediate PRBS” distinguishes a PRBS generated by flip-flops of a PRBS generator but not output from the PRBS generator from multiple bits of a PRBS output from the PRBS generator. In some embodiments, the flip-flops can be configured to generate a PRBS according to a Galois Field polynomial. However, in contrast to previous approaches, the PRBS generator 107 includes circuitry coupled to the flip-flops that enables the PRBS generator 107 to generate and output, during a single clock cycle, multiple bits of a PRBS corresponding to the current clock cycle as well as one or more subsequent clock cycle. In some embodiments, the PRBS output by the PRBS generator 107 can be based on the intermediate PRBS.

In some embodiments, the PRBS generator 107 can perform exclusive OR (XOR) operations on outputs of the flip-flops. Results of one or more of the XOR operations can be inputs of the flip-flops. One or more results of the XOR operations can be bits of the PRBS output from the PRBS generator 107. As described in association with FIGS. 2-5, the PRBS generator 107 can be configured to perform XOR operations on outputs of the flip-flops and provide one or more results of the XOR operations as inputs to the flip-flops to generate multiple bits of a PRBS during a single clock cycle.

The PRBS generator 107 can communicate the PRBS as multiple subsets (e.g., chunks, vectors) of the PRBS. The subsets can be of an equal bit length. The bit length can be based on the frequency of a data strobe signal of one or more of the memory devices 122. For instance, to perform operations associated with BIST of one or more of the memory devices 122, the memory devices 122 may need a respective bit of a PRBS each cycle of the data strobe signal. If the frequency of the data strobe signal is 16 times faster than the clock signal, then there are 16 cycles of the data strobe signal during a single cycle of the clock signal. Thus, the bit length of subsets can be 16 bits such that, during a single cycle of the clock signal, the PRBS generator 107 can provide 16 bits of a PRBS to the controller 100. The controller 100 can provide respective subsets of a PRBS to one or more of the memory devices 122 during a single cycle of the clock signal. In some embodiments, the controller 100 provides a subset of a PRBS to multiple memory devices simultaneously.

In some embodiments, one or more of the memory devices 122 can have a double date rate (DDR) interface such that data is captured on both the rising edge and the falling edge of the data strobe signal. If the frequency of the data strobe signal of a memory device having a DDR interface is 16 times faster than the clock signal, then there are 16 cycles of the data strobe signal during a single cycle of the clock signal, each of the 16 cycles having a rising edge and a falling edge. Thus, the bit length of subsets of a PRBS can be 32 bits such that, during a single cycle of the clock signal, the PRBS generator 107 provides 32 bits of a PRBS to the controller 100 (e.g., the back end portion 115). Thus, for a DDR interface, if the frequency of the data strobe signal is 16 times faster than the clock signal, then 32 bits of the PRBS can be communicated from the PRBS generator 107 to the controller 100 (and from the controller 100 to one or more of the memory devices 122) each clock cycle.

FIG. 2 is a block diagram representing flip-flops 230-0, 230-1, 230-2, and 230-3 (collectively referred to as the flip-flops 230) of a PRBS generator 207 in accordance with a number of embodiments of the present disclosure. For clarity, FIG. 2 has been simplified to focus on the flip-flops 230 of the PRBS generator 207. The PRBS generator 207 can be analogous to the PRBS generator 107 described in association with FIG. 1. The PRBS generated by the flip-flops 230 and the XOR operation 232 alone is the intermediate PRBS of the PRBS generator 207.

The example of the PRBS generator 207 is discussed in association with FIGS. 2-5. Although this example PRBS generator includes 4 flip-flops, embodiments of the present disclosure are not so limited. Embodiments of the present disclosure can include fewer than or greater than 4 flip-flops. The flip-flops 230 are configured to generate a PRBS according to a fourth-order Galois Field polynomial: p₄(x)=x⁴+x+1. However, embodiments of present disclosure can include generating a PRBS according to a lower order or higher order Galois Field polynomial. The output of the flip-flop s₀ 230-0 is an input to an XOR operation 232 (represented as a plus within a circle). The XOR operation 230 can be implemented via an XOR gate or other circuitry to perform an XOR operation). The result of the XOR operation 232 is input to the flip-flop s₁ 230-1. The output of the flip-flop s₁ 230-1 is an input to the flip-flop s₂ 230-2. The output of the flip-flop s₂ 230-2 is an input to the flip-flop s₃ 230-3. The output of the flip-flop s₃ 230-3 is an input to the flip-flop s₀ 230-0 and the XOR operation 232. The flip-flops 230 and the circuitry to perform the XOR operation 232 can comprise an LFSR.

To the right of the block diagram is a set of expressions 234 corresponding to the flip-flops 230 and the XOR operation 232. In the expressions 234, an XOR operation is represented by “+”. The current clock cycle is represented by “t”. The subsequent clock cycle is represented by “t+1”. The state of the flip-flop s₂ 230-2 during the current clock cycle is the state of the flip-flop s₃ 230-3 during the subsequent clock cycle. As used herein, a “state” of a flip-flop refers to a logical value (e.g., 1 or 0) output by the flip-flop. The state of the flip-flop s₁ 230-1 during the current clock cycle is the state of the flip-flop s₂ 230-2 during the subsequent clock cycle. The result of the XOR operation 230 on the states of the flip-flops s₀ 230-0 and s₂ 230-2 during the current clock cycle is the state of the flip-flop s₁ 230-1 during the subsequent clock cycle. The state of the flip-flop s₃ 230-3 during the current clock cycle is the state of the flip-flop s₀ 230-0 during the subsequent clock cycle.

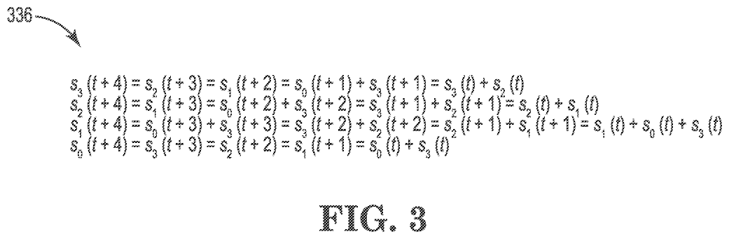

FIG. 3 illustrates a set of expressions 336 illustrative of generating a PRBS in accordance with a number of embodiments of the present disclosure. The expressions 336 are based on the expressions 234 corresponding to the flip-flops 230 and the XOR operation 232 described in association with FIG. 2. The expressions 336 represent the states of the flip-flops 230 for four consecutive clock cycles.

As described previously, the state of the flip-flop s₂ 230-2 at a clock cycle is the state of the flip-flop s₃ 230-3 at the subsequent clock cycle. Conversely, the state of the flip-flop s₃ 230-3 at a subsequent clock cycle is the state of the flip-flop s₂ 230-2 at the previous clock cycle. Therefore, as shown by the expressions 336, the state of the flip-flop s₃ 230-3 at 4 clock cycles in the future (represented by “t+4”) is the state of the flip-flop s₂ 230-2 at 3 clock cycles in the future (represented by “t+3”). The state of the flip-flop s₂ 230-2 at 3 clock cycles in the future is the state of the flip-flop s₁ 230-1 at 2 clock cycles in the future (represented by “t+2”), which is the result of the XOR operation 232 on the states of the flip-flops s₀ 230-0 and s₃ 230-3 at 1 clock cycle in the future (represented by “t+1”). From the expressions 234, the state of the flip-flop s₀ 230-0 at 1 clock cycle in the future is the state of the flip-flop s₃ 230-3 at the current clock cycle (represented by “t”) and the state of the flip-flop s₃ 230-3 at 1 clock cycle in the future is the state of the flip-flop s₂ 230-2 at the current clock cycle. Thus, as shown by the expressions 336, the state of the flip-flop s₃ 230-3 at 4 clock cycles in the future can be determined by an XOR operation performed on the states of the flip-flops s₂ 230-2 and s₃ 230-3 at the current clock cycle.

As shown by the expressions 336, the state of the flip-flop s₂ 230-2 at 4 clock cycles in the future is the state of the flip-flop s₁ 230-1 at 3 clock cycles in the future, which is the result of the XOR operation 232 on the states of the flip-flops s₀ 230-0 and s₃ 230-3 at 2 clock cycles in the future. The state of the flip-flop s₀ 230-0 at 2 clock cycles in the future is the state of the flip-flop s₃ 230-1 at 1 clock cycle in the future. The state of the flip-flop s₃ 230-3 at 2 clock cycles in the future is the state of the flip-flop s₂ 230-2 at 1 clock cycle in the future. From the expressions 234, the state of the flip-flop s₃ 230-3 at 1 clock cycle in the future is the state of the flip-flop s₂ 230-2 at the current clock cycle and the state of the flip-flop s₂ 230-2 at 1 clock cycle in the future is the state of the flip-flop s₁ 230-1 at the current clock cycle. Thus, as shown in the expressions 336, the state of the flip-flop s₂ 230-2 at 4 clock cycles in the future can be determined by an XOR operation performed on the states of the flip-flops s₂ 230-2 and s₁ 230-1 at the current clock cycle.

As shown by the expressions 336, the state of the flip-flop s₁ 230-1 at 4 clock cycles in the future is the result of the XOR operation 232 on the states of the flip-flops s₀ 230-0 and s₃ 230-3 at 3 clock cycles in the future. The state of the flip-flop s₀ 230-0 at 3 clock cycles in the future is the state of the flip-flop s₃ 230-1 at 2 clock cycles in the future, which is the state of the flip-flop s₂ 230-2 at 1 clock cycle in the future. The state of the flip-flop s₃ 230-3 at 3 clock cycles in the future is the state of the flip-flop s₂ 230-2 at 2 clock cycles in the future, which is the state of the flip-flop s₁ 230-1 at 1 clock cycle in the future. From the expressions 234, the state of the flip-flop s₂ 230-2 1 clock cycle in the future is the state of the flip-flop s₁ 230-1 at the current clock cycle. The state of the flip-flop s₁ 230-1 at 1 clock cycle in the future is the result of the XOR operation 232 on the states of the flip-flops s₀ 230-0 and s₃ 230-3 at the current clock cycle. Thus, as shown in the expressions 336, the state of the flip-flop s₁ 230-1 at 4 clock cycles in the future can be determined by an XOR operation performed on the state of the flip-flop s₁ 230-1 at the current clock cycle and the result of an XOR operation performed on the states of the flip-flops s₀ 230-0 and s₃ 230-3 at the current clock cycle.

As shown by the expressions 336, the state of the flip-flop s₀ 230-0 at 4 clock cycles in the future is the state of the flip-flop s₃ 230-3 at 3 clock cycles in the future. The state of the flip-flop s₃ 230-3 at 3 clock cycles in the future is the state of the flip-flop s₂ 230-2 at 2 clock cycles in the future, which is the state of the flip-flop s₁ 230-1 at 1 clock cycle in the future. From the expressions 234, the state of the flip-flop s₁ 230-1 at 1 clock cycle in the future is the result of the XOR operation 232 on the states of the flip-flops s₀ 230-0 and s₃ 230-3 at the current clock cycle. Thus, as shown by the expressions 336, the state of the flip-flop s₀ 230-0 at 4 clock cycles in the future can be determined by an XOR operation performed on the states of the flip-flops s₀ 230-0 and s₃ 230-3 at the current clock cycle.

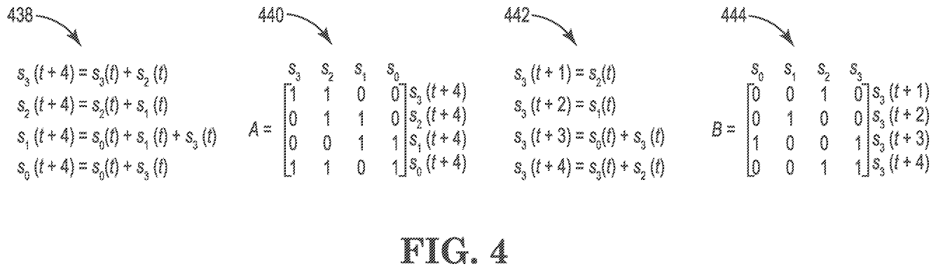

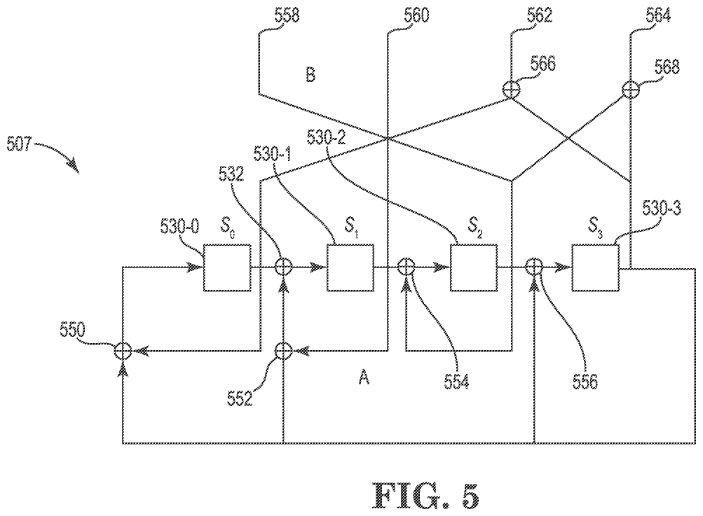

FIG. 4 illustrates sets of expressions 438 and 442 and corresponding matrices 440 and 444 illustrative of generating a PRBS in accordance with a number of embodiments of the present disclosure. The expressions 438 are simplified versions of the expressions 336 described in association with FIG. 3 showing the end result. The expressions 438 determine the states of the flip-flops 230, described in association with FIG. 2, 4 clock cycles in the future based on states of the flip-flops 230 at a current clock cycle. The matrices 440 and 444 can facilitate implementing the expressions in the PRBS generator 507 described in association with FIG. 5.

The matrix A 440 can be referred to as the dynamic matrix. The matrix A 440 corresponds to the expressions 438. The columns of the matrix A 440, from left to right, correspond to the flip-flop s₃ 230-3, the flip-flop s₂ 230-2, the flip-flop s₁ 230-1, and the flip-flop s₀ 230-0, respectively. Each respective row of the matrix A 440 indicates states which of the flip-flops 230 on which one or more XOR operations can be performed to determine states of respective flip-flops 230 4 clock cycles in the future. The rows of the matrix A 440, from top to bottom, correspond to states of the flip-flop s₃ 230-3, the flip-flop s₂ 230-2, the flip-flop s₁ 230-1, and the flip-flop s₀ 230-0, respectively, at 4 clock cycles in the future.

The expressions 442 determine the states of the flip-flop s₃ 230-3 at 1, 2, 3, and 4 clock cycles in the future, respectively, and are derived from the expressions 234 and 336. The matrix B 444 can be referred to as the output matrix. The matrix B 444 corresponds to the expressions 442. The columns of the matrix B 444, from left to right, correspond to the flip-flop s₀ 230-0, the flip-flop s₁ 230-1, the flip-flop s₂ 230-2, and the flip-flop s₃ 230-3, respectively. Each respective row of the matrix B 444 indicates states which of the flip-flops 230 on which one or more XOR operations can be performed to determine the states of the flip-flop s₃ 230-3 at 1, 2, 3, and 4 clock cycles in the future, respectively. The rows of the matrix A 444, from top to bottom, correspond to the states of the flip-flop s₃ 230-3 at 1, 2, 3, and 4 clock cycles in the future, respectively.

FIG. 5 is a block diagram of a PRBS generator 507 in accordance with a number of embodiments of the present disclosure. The PRBS generator 507 can be analogous to the PRBS generator 107 described in association with FIG. 1. The flip-flops 530 and the XOR operation 532 can be analogous to the flip-flops 230 and the XOR operation 232 described in association with FIG. 2. FIG. 5 illustrates circuitry of the PRBS generator 507 not shown in FIG. 2.

FIG. 5 illustrates additional connections to the flip-flops 530 and additional XOR operations performed on states of the flip-flops 530. The additional connections and XOR operations illustrated below the flip-flops 530 correspond to the matrix A 440 described in association with FIG. 4. The XOR operation 556 corresponds to the XOR operation, indicated by the first row of the matrix A 440, on the states of the flip-flops s₂ 230-2 and s₃ 230-3 at the current clock cycle to determine the state of the flip-flop s₃ 230-3 at 4 clock cycles in the future. The XOR operation 554 corresponds to the XOR operation, indicated by the second row of the matrix A 440, on the states of the flip-flops s₁ 230-1 and s₂ 230-2 at the current clock cycle to determine the state of the flip-flop s₂ 230-2 at 4 clock cycles in the future. The XOR operations 532 and 552 correspond to the XOR operations, indicated by the third row of the matrix A 440, on the states of the flip-flops s₀ 230-0, s₁ 230-1, and s₃ 230-3 at the current clock cycle to determine the state of the flip-flop s₁ 230-1 at 4 clock cycles in the future. The XOR operation 550 corresponds to the XOR operation, indicated by the fourth row of the matrix A 440, on the states of the flip-flops s₀ 230-0 and s₃ 230-3 at the current clock cycle to determine the state of the flip-flop s₀ 230-0 at 4 clock cycles in the future.

The additional connections and XOR operations illustrated above the flip-flops 530 correspond to the matrix B 444. The connection 558 to the output of the flip-flop s₂ 230-2 corresponds to the state of the flip-flop s₃ 230-3 at 1 clock cycle in the future being the state of the flip-flop s₂ 230-2 at the current clock cycle as indicated by the first row of the matrix B 444. The connection 560 to the output of the flip-flop s₁ 230-1 corresponds to the state of the flip-flop s₃ 230-3 at 2 clock cycles in the future being the state of the flip-flop s₁ 230-1 at the current clock cycle as indicated by the second row of the matrix B 444. The XOR operation 566 and result of the XOR operation 566 represented by the connection 560 correspond to an XOR operation on the states of the flip-flops s₀ 230-0 and s₃ 230-3 at the current clock cycle being the state of the flip-flop s₃ 230-3 at 3 clock cycles in the future as indicated by the third row of the matrix B 444. The XOR operation 568 and result of the XOR operation 568 represented by the connection 562 correspond to an XOR operation on the states of the flip-flops s₂ 230-2 and s₃ 230-3 at the current clock cycle being the state of the flip-flop s₃ 230-3 at 4 clock cycles in the future as indicated by the fourth row of the matrix B 444.

In contrast to some previous approaches to a PRBS generator that output a single bit of a PRBS each clock cycle, the circuitry of the PRBS generator 507 corresponding to the matrix A 440 and the matrix B 444 enable the PRBS generator 507 to generate 4 bits of a PRBS each clock cycle. The PRBS generator 507 outputs a bit at each of the connections 558, 560, 562, and 564 each clock cycle. Specifically, a bit indicative of the state of the flip-flop s₃ 530-3 at 1 clock cycle in the future is output at the connection 558. A bit indicative of the state of the flip-flop s₃ 530-3 at 2 clock cycles in the future is output at the connection 560. A bit indicative of the state of the flip-flop s₃ 530-3 at 3 clock cycles in the future is output at the connection 562. A bit indicative of the state of the flip-flop s₃ 530-3 at 4 clock cycles in the future is output at the connection 562.

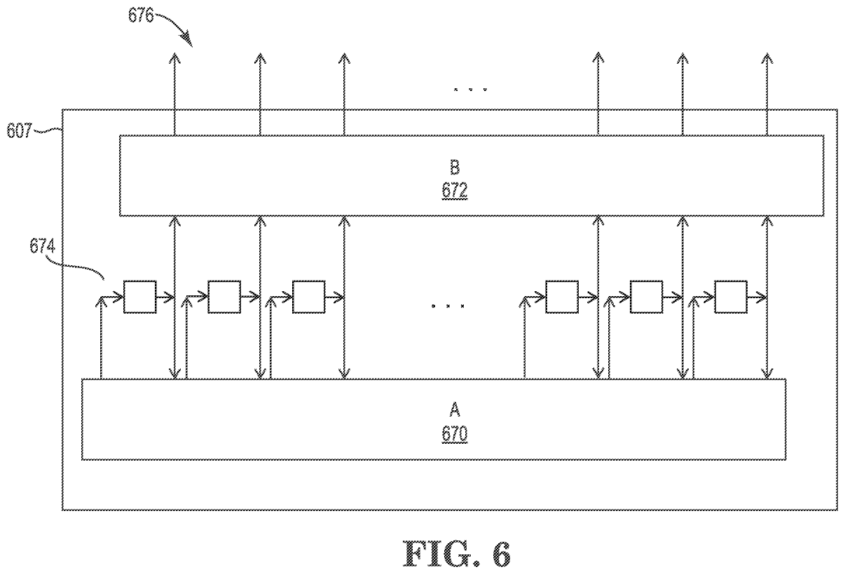

FIG. 6 is a block diagram of a PRBS generator 607 in accordance with a number of embodiments of the present disclosure. A particular example of a PRBS generator in accordance with the present disclosure having 4 flip-flops is described in association with FIGS. 2-5. In contrast, the PRBS generator 607 illustrated by FIG. 6 is applicable to different quantities of flip-flops.

The flip-flops 674 are representative of any quantity (e.g., 8, 16, 32) of flip-flops. As described in association with FIGS. 2-3, states of the flip-flops 674 at one or more clock cycles in the future can be determined and expressed in terms of states of the flip-flops 674 at the current clock cycle. As described in association with FIG. 4, expressions of states of the flip-flops 674 at one or more clock cycles in the future can be expressed in matrix form, which can facilitate implementing the expressions in the PRBS generator 607.

Circuitry 670 is shown as a rectangle but represents circuitry (e.g., connections between the flip-flops 674 and/or implementation of XOR operations) corresponding to the dynamic matrix, such as the matrix A 440 described in association with FIG. 4. Circuitry 672 is shown as a rectangle but represents circuitry (e.g., connections between the flip-flops 674 and/or implementation of XOR operations) corresponding to the output matrix, such as the matrix B 444. Although FIG. 6 illustrates respective connections to the circuitry 670 and the circuitry 672 for each of the flip-flops 674, embodiments of the present disclosure are not so limited. For example, in some embodiments, outputs of one or more of the flip-flops 674 may not be coupled or provided to the circuitry 670 and/or the circuitry 672. As illustrated by FIG. 6, the PRBS generator 607 includes multiple connections 676 (e.g., pins) from the circuitry 672. Multiple bits of a PRBS can be output from the PRBS generator 607 each clock cycle via the connections 676.

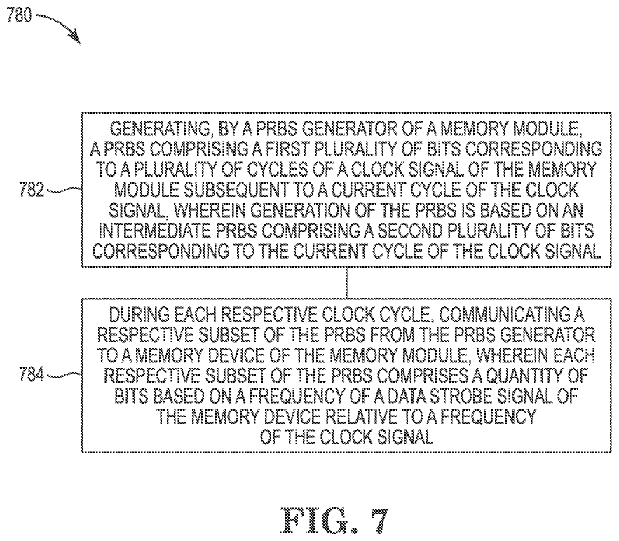

FIG. 7 is a flow diagram of a method 780 for generating a PRBS in accordance with a number of embodiments of the present disclosure. Any of the steps and operations of the flow diagram 780 can be performed by the PRBS generator 107 described in association with FIG. 1, for example.

At 782, the method 780 can include generating, by a PRBS generator of a memory module, a PRBS including a first plurality of bits corresponding to a plurality of cycles of a clock signal of the memory module subsequent to a current cycle of the clock signal. Generation of the PRBS can be based on an intermediate PRBS including a second plurality of bits corresponding to the current cycle of the clock signal. Generating the PRBS can include performing a number of XOR operations on the second plurality of bits of the intermediate PRBS. Generating the PRBS can include generating the respective subset of the PRBS during the current cycle of the clock signal.

At 784, the method 780 can include, during each respective cycle of the clock signal, communicating a respective subset of the PRBS from the PRBS generator to a memory device of the memory module. Each respective subset of the PRBS can include a quantity of bits based on a frequency of a data strobe signal of the memory device relative to a frequency of the clock signal. The frequency of the data strobe signal can be at least twice (e.g., sixteen times) as fast as the first frequency of the clock signal. The quantity of bits can be thirty-two bits.

Although specific embodiments have been illustrated and described herein, those of ordinary skill in the art will appreciate that an arrangement calculated to achieve the same results can be substituted for the specific embodiments shown. This disclosure is intended to cover adaptations or variations of one or more embodiments of the present disclosure. It is to be understood that the above description has been made in an illustrative fashion, and not a restrictive one. Combination of the above embodiments, and other embodiments not specifically described herein will be apparent to those of skill in the art upon reviewing the above description. The scope of the one or more embodiments of the present disclosure includes other applications in which the above structures and processes are used. Therefore, the scope of one or more embodiments of the present disclosure should be determined with reference to the appended claims, along with the full range of equivalents to which such claims are entitled.

In the foregoing Detailed Description, some features are grouped together in a single embodiment for the purpose of streamlining the disclosure. This method of disclosure is not to be interpreted as reflecting an intention that the disclosed embodiments of the present disclosure have to use more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separate embodiment.

What is claimed is:

1. A method, comprising:
generating, by a pseudorandom binary sequence (PRBS) generator of a memory module, a PRBS comprising a first plurality of bits corresponding to a plurality of cycles of a clock signal of the memory module subsequent to a current cycle of the clock signal,
wherein generation of the PRBS is based, at least in part, on an intermediate PRBS comprising a second plurality of bits corresponding to the current cycle of the clock signal; and
during each respective cycle of the clock signal, communicating a respective subset of the PRBS from the PRBS generator to a memory device of the memory module, wherein each respective subset of the PRBS comprises a quantity of bits based, at least in part, on a frequency of a data strobe signal of the memory device relative to a frequency of the clock signal.

2. The method of claim 1, wherein the frequency of the data strobe signal is at least twice as fast as the frequency of the clock signal.

3. The method of claim 1, wherein the frequency of the data strobe signal is sixteen (16) times faster than the frequency of the clock signal.

4. The method of claim 1, wherein the quantity of bits is thirty-two (32) bits.

5. The method of claim 1, wherein generating the PRBS comprises performing a number of exclusive OR (XOR) operations on the second plurality of bits of the intermediate PRBS.

6. The method of claim 1, wherein generating the PRBS comprises generating the respective subset of the PRBS during the current cycle of the clock signal.

7. An apparatus, comprising:
a plurality of flip-flops;
first circuitry coupled to the plurality of flip-flops and configured to:
receive a first plurality of outputs of the plurality of flip-flops;
perform an exclusive OR (XOR) operation on two of the first plurality of outputs; and
provide, to the plurality of flip-flops, a number of inputs based, at least in part, on the first number of outputs, wherein the number of inputs comprises a result of the XOR operation; and
second circuitry coupled to the plurality of flip-flops and configured to:
receive a second plurality of outputs from the plurality of flip-flops;
generate a pseudorandom binary sequence (PRBS) based, at least in part, on the second plurality of outputs; and
communicate the PRBS as a plurality of subsets of the PRBS of an equal bit length, wherein the bit length is greater than one bit and based, at least in part, on a frequency of a data strobe signal of a memory device.

8. The apparatus of claim 7, wherein the second circuitry is further configured to communicate respective subsets of the plurality each cycle of a clock signal.

9. The apparatus of claim 8, wherein the plurality of flip-flops are configured to generate an intermediate PRBS.

10. The apparatus of claim 9, wherein the second circuitry is further configured to:
generate a respective plurality of bits of the PRBS each cycle of the clock signal to yield the plurality of subsets of the PRBS; and
communicate the respective plurality of bits each cycle of the clock signal.

11. The apparatus of claim 7, further comprising a controller coupled to the memory device and the second circuitry, and
wherein the second circuitry is further configured to communicate the plurality of subsets to the controller.

12. The apparatus of claim 7, wherein the second circuitry is further configured to:
perform a number of exclusive OR (XOR) operations on the second plurality of outputs of the plurality of flip-flips; and
communicate a result of the number of XOR operations as a bit of the PRBS.

13. The apparatus of claim 7, wherein the plurality of flip-flops are configured to generate an intermediate PRBS according to a Galois Field polynomial.

14. The apparatus of claim 7, wherein the first circuitry comprises a first number of exclusive OR (XOR) gates coupled to the plurality of flip-flops, and
wherein the second circuitry comprises a second number of XOR gates coupled to the plurality of flip-flops.

15. An apparatus, comprising:
a memory device configured to receive a data strobe signal and a pseudorandom binary sequence (PRBS) at a first frequency associated with the data strobe signal;
a controller coupled to the memory device and configured to receive a clock signal, wherein the controller comprises a PRBS generator comprising:
first circuitry configured to generate an intermediate PRBS at a second frequency associated with the clock signal; and
second circuitry coupled to the first circuitry and configured to:
generate the PRBS based at least in part on the intermediate PRBS; and
provide the PRBS to the controller.

16. The apparatus of claim 15, wherein the controller further comprises:
a central controller portion comprising the PRBS generator; and
a back end portion coupled to the memory device,
wherein the second circuitry is further configured to provide respective pluralities of bits of the PRBS to the back end portion each cycle of the clock signal,
wherein the memory device is one of a plurality of memory devices, and
wherein the back end portion is configured to communicate the respective pluralities of bits of the PRBS to the plurality of memory devices simultaneously.

17. The apparatus of claim 16, wherein a quantity of the respective pluralities of bits of the PRBS is based at least in part on a ratio of a frequency of the data strobe signal relative to a frequency of the clock signal.

18. The apparatus of claim 15, wherein the memory device comprises a double data rate (DDR) interface.

19. The apparatus of claim 15, wherein the second circuitry is further configured to:
generate, during a current cycle of the clock signal, a first bit of the intermediate PRBS corresponding to a first cycle of the clock signal subsequent to the current cycle of the clock signal; and
generate, during the current cycle of the clock signal, a second bit of the intermediate PRBS corresponding to a second cycle of the clock signal subsequent to the first cycle of the clock signal,
wherein the PRBS provided by the second circuitry comprises the first and second bits of the intermediate PRBS.

20. The apparatus of claim 19, wherein the second circuitry is further configured to generate, during the current cycle of the clock signal, a third bit of the intermediate PRBS corresponding to a third cycle of the clock signal subsequent to the second cycle of the clock signal,
wherein the PRBS provided by the second circuitry comprises the first, second, and third bits of the intermediate PRBS.
